(19) United States
(12) Patent Application Publication
(10) Pub. No.: US 2014/0151665 A1
(43) Pub. Date: Jun. 5, 2014

(54) CARBAZOLE DERIVATIVE AND ORGANIC ELECTROLUMINESCENCE DEVICE USING THE SAME

(71) Applicant: SAMSUNG DISPLAY CO., LTD., Yongin-City (KR)

(72) Inventor: Shuri SATO, Yongin-City (KR)

(73) Assignee: SAMSUNG DISPLAY CO., LTD., Yongin-City (KR)

(21) Appl. No.: 14/093,774

(22) Filed: Dec. 2, 2013

(30) Foreign Application Priority Data
Nov. 30, 2012 (JP) 2012-261896

(51) Int. Cl. H01L 51/00

(52) U.S. Cl. CPC H01L 51/0072; H01L 51/0067
USPC 257/40; 544/180; 546/50; 252/519.21

(57) ABSTRACT

An indolo[3,2,1-jk] carbazole derivative is represented by the following Formula 1.

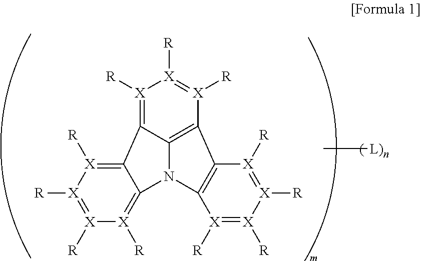

In Formula 1, X is a carbon atom or a nitrogen atom. At least one of X is a nitrogen atom. when X is a nitrogen atom, R is not present. When X is a carbon atom, R is hydrogen, an alkyl group, an alkoxy group, an aryl group, or a heteroaryl group. L is an electron acceptor, and m and n represent an integer of greater than or equal to 1.

### CROSS-REFERENCE TO RELATED APPLICATION

Japanese Patent Application No. 2012-261896, filed on Nov. 30, 2012, in the Korean Intellectual Property Office, and entitled: “CARBAZOLE DERIVATIVE AND ORGANIC ELECTROLUMINESCENCE DEVICE USING THE SAME,” is incorporated by reference herein in its entirety.

### BACKGROUND

1. Field

Embodiments relate to a carbazole derivative and an organic electroluminescence device using the same.

2. Description of the Related Art

In recent years, organic electroluminescence (EL) displays, which are one type of image displays, have been actively developed. Unlike a liquid crystal display and the like, the organic EL display is a self-luminescent display in which holes and electrons injected from a positive electrode and a negative electrode are recombined in an emission layer to thus emit a light from a light-emitting material including an organic compound of the emission layer, thereby displaying an image.

An example of a general light-emitting device may include an organic EL device that includes a positive electrode, a hole transport layer on the positive electrode, an emission layer on the hole transport layer, an electron transport layer on the emission layer, and a negative electrode on the electron transport layer. Holes injected from the positive electrode may be transported into the emission layer via the hole transport layer. Electrons are injected from the negative electrode, and then transported into the emission layer via the electron transport layer. The holes and the electrons injected into the emission layer recombine to generate excitons within the emission layer. The organic EL device emits a light by using light generated by radiation and deactivation of the excitons. The organic EL device may be provided in various forms.

### SUMMARY

Embodiments are directed to an indolo[3,2,1-jk] carbazole derivative, in which an indolo[3,2,1-jk] carbazole skeleton and an electron acceptor are combined, and at least one carbon atom of a benzene ring forming the indolo[3,2,1-jk] carbazole skeleton is replaced with a nitrogen atom.

L in Formula 1 may be a pyridine derivative, a pyrimidine derivative, a triazine derivative, an imidazole derivative, a dibenzofuran derivative, or a dibenzothiophene derivative.

The indolo[3,2,1-jk] carbazole derivative may be represented by the following Formula 1:

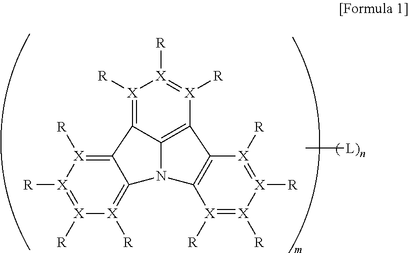

wherein X may be a carbon atom or a nitrogen atom. At least one of X may be a nitrogen atom. When X is a nitrogen atom, R is not present. When X is a carbon atom, R may be hydrogen, an alkyl group, an alkoxy group, an aryl group, or a heteroaryl group. L may be an electron acceptor, and m and n may represent an integer of greater than or equal to 1.

L in Formula 1 may be a pyridine derivative, a pyrimidine derivative, a triazine derivative, an imidazole derivative, a dibenzofuran derivative, or a dibenzothiophene derivative.

The indolo[3,2,1-jk] carbazole derivative may be a compound represented by one of the following formulas:

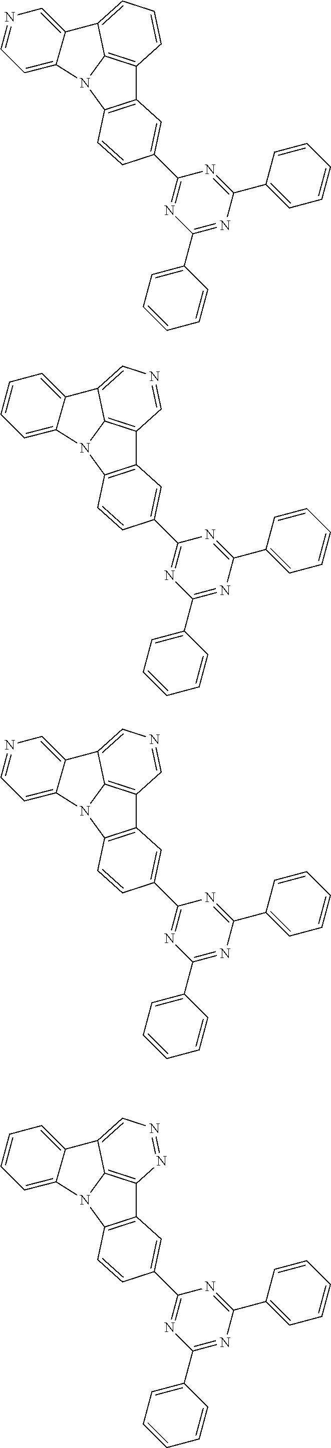

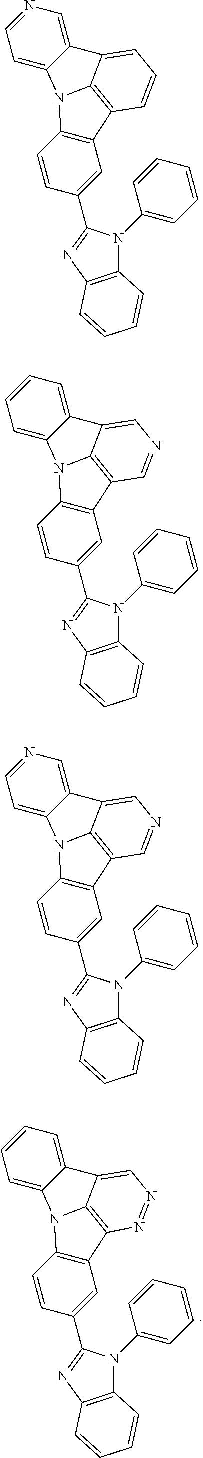 [SMILES: c1ccc(-n2c(-c3ccc4c(c3)c3cccc5c6cnccc6n4c53)nc3ccccc32)cc1 ; c1ccc(-n2c(-c3ccc4c(c3)c3cncc5c6ccccc6n4c53)nc3ccccc32)cc1 ; c1ccc(-n2c(-c3ccc4c(c3)c3cncc5c6cnccc6n4c53)nc3ccccc32)cc1 ; c1ccc(-n2c(-c3ccc4c(c3)c3nncc5c6ccccc6n4c53)nc3ccccc32)cc1]

Embodiments are also directed to an organic electroluminescence device including an emission layer including an indolo[3,2,1-jk] carbazole derivative, in which an indolo[3,2,1-jk] carbazole skeleton and an electron acceptor are combined, and at least one carbon atom of a benzene ring forming the indolo[3,2,1-jk] carbazole skeleton is replaced with a nitrogen atom.

The indolo[3,2,1-jk] carbazole derivative may be represented by following Formula 1:

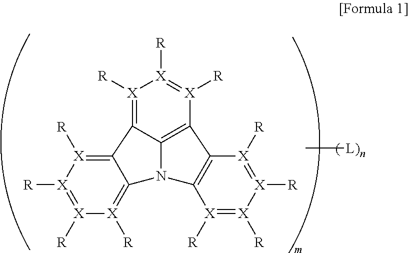

wherein X may be a carbon atom or a nitrogen atom. At least one of X may be a nitrogen atom. When X is a nitrogen atom, R is not present. When X is a carbon atom, R may be hydrogen, an alkyl group, an alkoxy group, an aryl group, or a heteroaryl group. L may be an electron acceptor, and m and n may represent an integer of greater than or equal to 1.

L in Formula 1 may be a pyridine derivative, a pyrimidine derivative, a triazine derivative, an imidazole derivative, a dibenzofuran derivative, or a dibenzothiophene derivative.

The indolo[3,2,1-jk] carbazole derivative may be a compound represented by one of the following formulas:

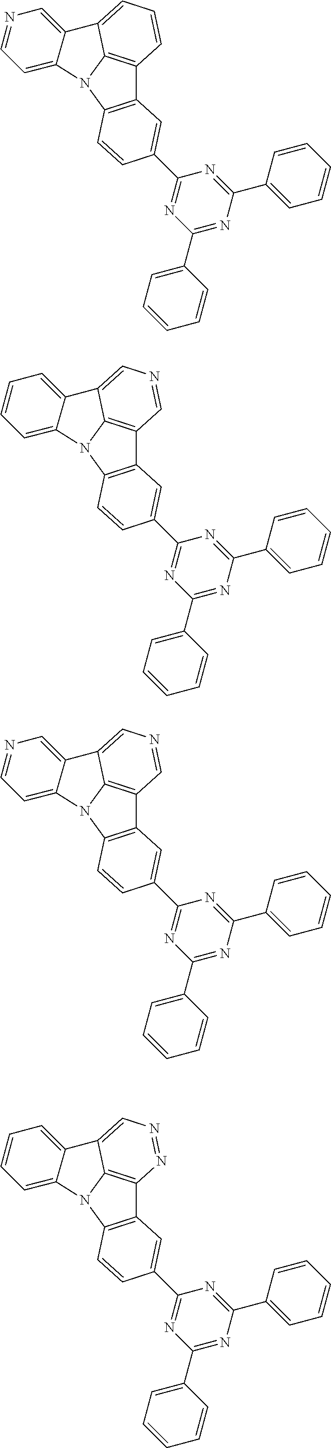

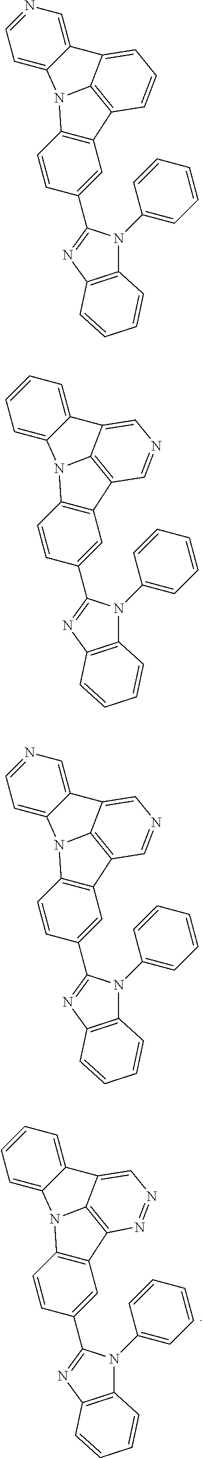 [SMILES: c1ccc(-n2c(-c3ccc4c(c3)c3cccc5c6cnccc6n4c53)nc3ccccc32)cc1 ; c1ccc(-n2c(-c3ccc4c(c3)c3cncc5c6ccccc6n4c53)nc3ccccc32)cc1 ; c1ccc(-n2c(-c3ccc4c(c3)c3cncc5c6cnccc6n4c53)nc3ccccc32)cc1 ; c1ccc(-n2c(-c3ccc4c(c3)c3nncc5c6ccccc6n4c53)nc3ccccc32)cc1]

Embodiments are also directed to an organic electroluminescence device including an intermediate layer between a hole transport layer and an emission layer, wherein the intermediate layer includes an indolo[3,2,1-jk] carbazole derivative, in which an indolo[3,2,1-jk] carbazole skeleton and an electron acceptor are combined, and at least one carbon atom of a benzene ring forming the indolo[3,2,1-jk] carbazole skeleton is replaced with a nitrogen atom.

The indolo[3,2,1-jk] carbazole derivative may be represented by following Formula 1:

[Formula 1]

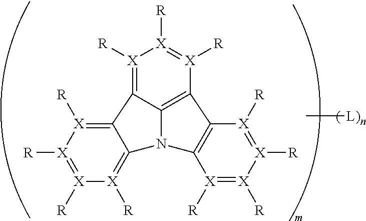

wherein X is a carbon atom or a nitrogen atom. At least one of X may be a nitrogen atom. When X is a nitrogen atom, R is not present. When X is a carbon atom, R may be hydrogen, an alkyl group, an alkoxy group, an aryl group, or a heteroaryl group. L may be an electron acceptor, and m and n may represent an integer of greater than or equal to 1.

L in Formula 2 may be a pyridine derivative, a pyrimidine derivative, a triazine derivative, an imidazole derivative, a dibenzofuran derivative, or a dibenzothiophene derivative.

The indolo[3,2,1-jk] carbazole derivative may be a compound represented by one of the following formulas:

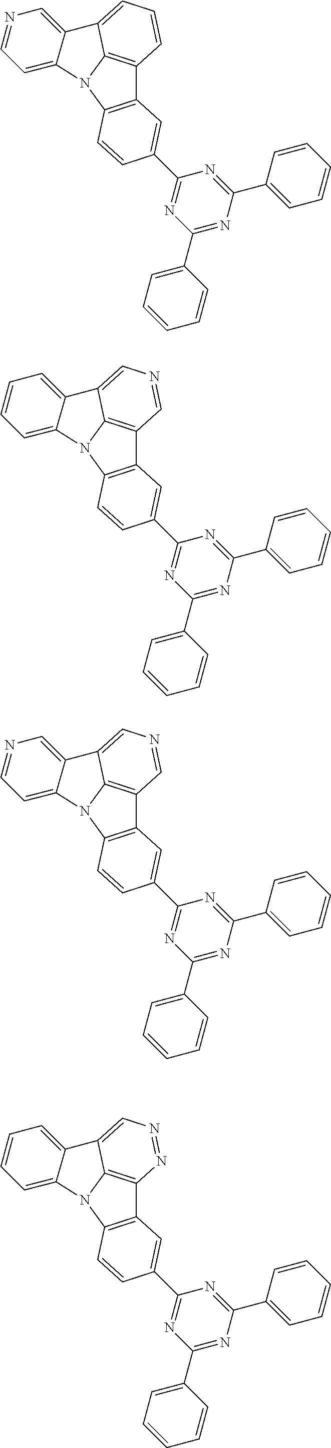

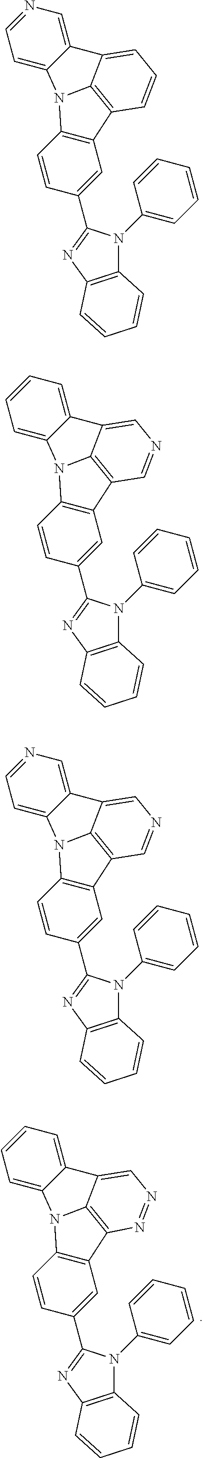 [SMILES: c1ccc(-n2c(-c3ccc4c(c3)c3cccc5c6cnccc6n4c53)nc3ccccc32)cc1 ; c1ccc(-n2c(-c3ccc4c(c3)c3cncc5c6ccccc6n4c53)nc3ccccc32)cc1 ; c1ccc(-n2c(-c3ccc4c(c3)c3cncc5c6cnccc6n4c53)nc3ccccc32)cc1 ; c1ccc(-n2c(-c3ccc4c(c3)c3nncc5c6ccccc6n4c53)nc3ccccc32)cc1]

### BRIEF DESCRIPTION OF THE DRAWINGS

Features will become apparent to those of skill in the art by describing in detail exemplary embodiments with reference to the attached drawings in which:

FIG. 1 illustrates a schematic diagram depicting an organic EL device 100 according to an embodiment;

FIG. 2 illustrates a schematic diagram depicting an organic EL device 200 according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Hereinafter, exemplary embodiments of an indolo[3,2,1-jk] carbazole derivative, and an organic EL device including the same will be described in detail with reference to the accompanying drawings. The indolo[3,2,1-jk] carbazole derivative and the organic EL device using the same may, however, be embodied in different forms and should not be construed as limited to the embodiments set forth herein.

The indolo[3,2,1-jk] carbazole derivative has a combined structure of indolo[3,2,1-jk] carbazole and an electron acceptor. In addition, in the indolo[3,2,1-jk] carbazole derivative, at least one carbon of a benzene ring forming an indolo[3,2,1-jk] carbazole skeleton is replaced with nitrogen. The indolo[3,2,1-jk] carbazole derivative may exhibit improved hole donor properties by replacing at least one carbon of a benzene ring forming the indolo[3,2,1-jk] carbazole skeleton in the indolo[3,2,1-jk] carbazole derivative with nitrogen. In addition, by adding the electron acceptor to the indolo[3,2,1-jk] carbazole skeleton, a host material for an organic EL device having bipolar properties having increased electron affinity may be realized.

More particularly, the indolo[3,2,1-jk] carbazole derivative may be represented by the following Formula 1.

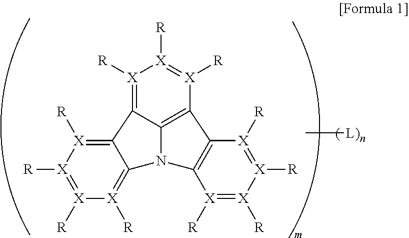

In Formula 1, X is carbon or nitrogen and at least one of X is nitrogen. When X is nitrogen, R is not present. When X is carbon, R may be hydrogen, an alkyl group, an alkoxy group, an aryl group, or a heteroaryl group. L is an electron acceptor, and m and n represent an integer of greater than or equal to 1.

The position or number of substituted nitrogen atoms is selectable. According to an implementation, all of the X's are not substituted with nitrogen. According to another implementation, nitrogen atoms are not directly adjacent to each other in a benzene ring of the indolo[3,2,1-jk] carbazole skeleton. The material for the organic EL device may have a substituent having a large size and may restrain a stack phenomenon, which may be easily generated between phenyl groups, by replacing at least one carbon constituting a benzene ring forming the indolo[3,2,1-jk] carbazole skeleton in the indolo[3,2,1-jk] carbazole derivative with nitrogen. Then, the amorphous properties of the material may be improved, and the dispersibility of dopants with respect to the host may be increased. The indolo[3,2,1-jk] carbazole derivative may be a host material that may improve the hole donor properties and may attain the high efficiency and the long life, by replacing at least one carbon of the benzene ring forming the indolo[3,2,1-jk] carbazole skeleton with nitrogen.

The term “alkyl group” may refer to a methyl group, an ethyl group, a propyl group, an isopropyl group, a butyl group, an isobutyl group, a sec-butyl group, a tert-butyl group, a pentyl group, an isoamyl group, a hexyl group, a cyclohexyl group, an heptyl group, an octyl group, a 2-ethyl hexyl group, a nonyl group, a decyl group, a 3,7-dimethyl octyl group, a dodecyl group, a trifluoromethyl group, a pentafluoroethyl group, a perfluorobutyl group, a perfluorohexyl group, a perfluorooctyl group, or the like.

The term “alkoxy group” may refer to a methoxy group, an ethoxy group, or the like.

The term “aryl group” may refer to a monocyclic, dicyclic, or tricyclic aromatic hydrocarbon, excluding one hydrogen atom, and may have a substituent. In an implementation, the aryl group may include a phenyl group, a biphenylyl group, a C₁-C₁₂ alkoxyphenyl group, a C₁-C₁₂ alkylphenyl group, a 1-naphthyl group, a 2-naphthyl group, a 1-anthracenyl group, a 2-anthracenyl group, a 9-anthracenyl group, a 2-fluorenyl group, a pentafluorophenyl group, a biphenylyl group, a C₁-C₁₂ alkoxybiphenylyl group, a C₁-C₁₂ alkylbiphenylyl group, or the like.

The term “heteroaryl group may refer to of monocyclic, dicyclic, or tricyclic aromatic compound including one or a plurality of hetero atoms, excluding one hydrogen atom. In an embodiment, the heteroaryl group may include thienyl, benzothienyl, furyl, benzofuryl, pyrrolyl, imidazolyl, benzoimidazolyl, thiazolyl, benzothiazolyl, isothiazolyl, benzoisothiazolyl, pyrazolyl, oxazolyl, benzoxazolyl, isoxazolyl, benzoisoxazolyl, isothiazolyl, triazolyl, benzotriazolyl, thiadiazolyl, oxadiazolyl, pyridinyl, pyridazinyl, pyrimidinyl, triazinyl, indolyl, indazolyl, or the like.

In the above Formula 1, L may be an electron acceptor selected from, for example, a pyridine derivative, a pyrimidine derivative, a triazine derivative, an imidazole derivative, a dibenzofuran derivative, or a dibenzothiophene derivative. The indolo[3,2,1-jk] carbazole derivative may have electron acceptor and electron transport capabilities, and may provide high efficiency and long life.

The indolo[3,2,1-jk] carbazole derivative may be one of the following compounds:

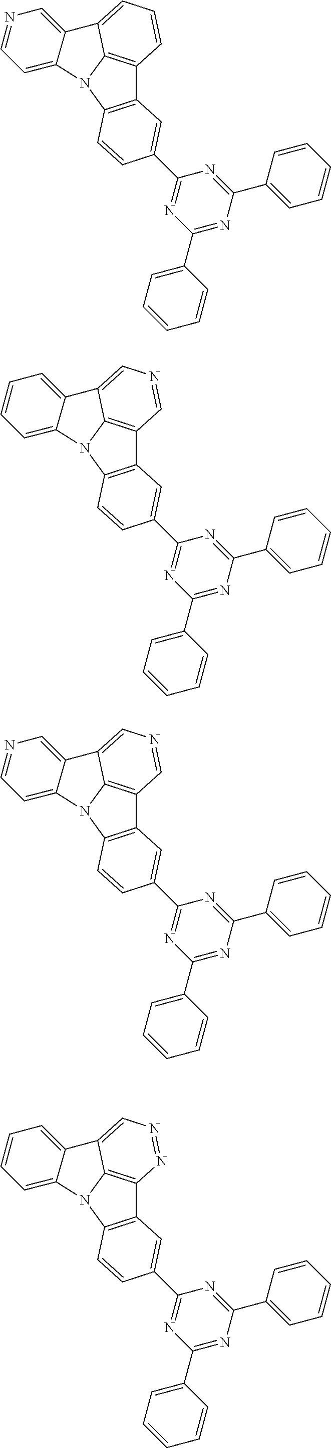

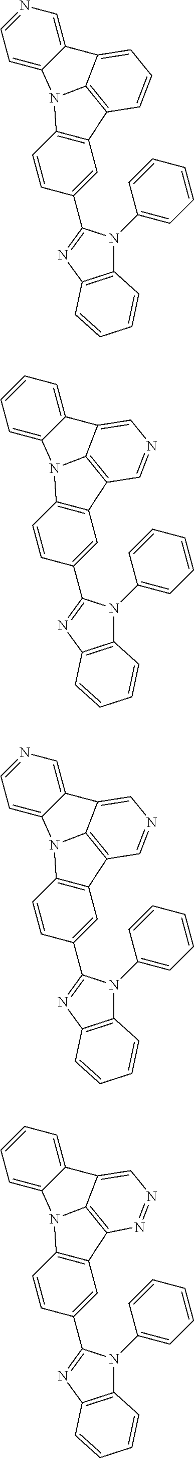 [SMILES: c1ccc(-n2c(-c3ccc4c(c3)c3cccc5c6cnccc6n4c53)nc3ccccc32)cc1 ; c1ccc(-n2c(-c3ccc4c(c3)c3cncc5c6ccccc6n4c53)nc3ccccc32)cc1 ; c1ccc(-n2c(-c3ccc4c(c3)c3cncc5c6cnccc6n4c53)nc3ccccc32)cc1 ; c1ccc(-n2c(-c3ccc4c(c3)c3nncc5c6ccccc6n4c53)nc3ccccc32)cc1]

As described above, in the indolo[3,2,1-jk] carbazole derivative, at least one carbon of a benzene ring forming the indolo[3,2,1-jk] carbazole skeleton is replaced with nitrogen. Thus, a large-sized substituent is included in the derivative, and a stack phenomenon between molecules, which may be easily generated between phenyl groups, may be restrained. In addition, carrier exchange between molecules may not be damaged not by imparting a large-sized substituent but by providing a site having a large volume. Therefore, the amorphous properties of the material may be improved, and the dispersibility of dopants with respect to a host may be increased. The indolo[3,2,1-jk] carbazole derivative may have an electron acceptor. Accordingly, electron transport properties, high efficiency, and long life may be realized.

Organic EL Device

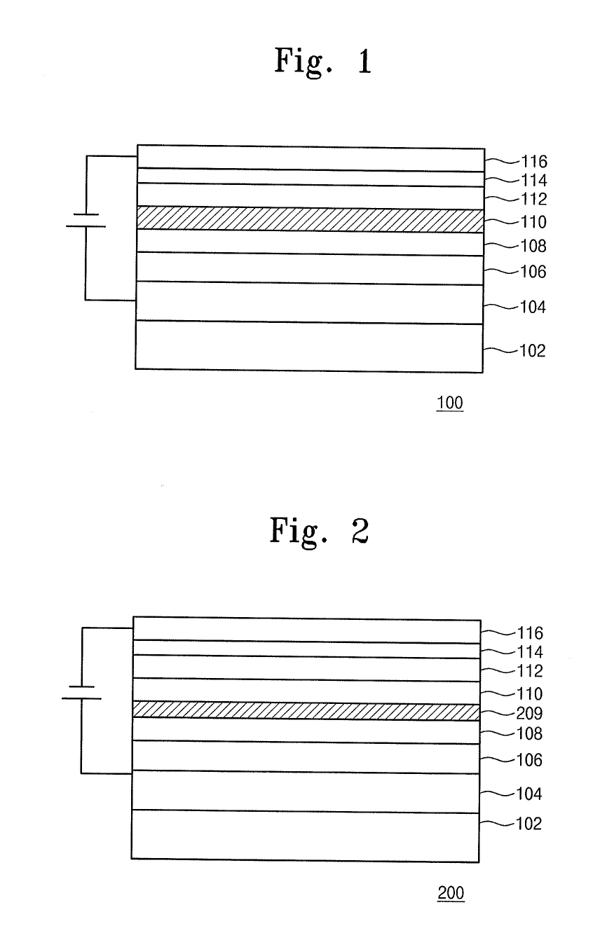

As described above, the indolo[3,2,1-jk] carbazole derivative having high amorphous properties and good bipolar properties may be appropriately used as a material for forming an emission layer, or an intermediate layer between a hole transport layer and the emission layer of an organic EL device. Hereinafter an organic EL device including the indolo[3,2,1-jk] carbazole derivative will be explained. FIG. 1 is a schematic diagram illustrating an organic EL device 100 according to an embodiment. The organic EL device 100 includes, for example, a substrate 102, a positive electrode 104, a hole injection layer 106, a hole transport layer 108, an emission layer 110, an electron transport layer 112, an electron injection layer 114, and a negative electrode 116.

The substrate 102 may be, for example, a transparent glass substrate, a flexible substrate of a semiconductor substrate resin including silicon, or the like. The positive electrode 104 may be on the substrate 102 and may be formed by using indium tin oxide (ITO), indium zinc oxide (IZO), or the like. The hole injection layer 106 may be on the positive electrode 104 and may include 4,4′,4″-tris(N-1-naphthyl-N-phenylamino)triphenylamine (1-TNATA), or the like. The hole transport layer 108 may be on the hole injection layer 106 and may be formed by using, for example, α-N,N′-bis(1-naphthyl)-N,N′-biphenyl-benzidine (α-NPD), N,N′-bis(3-methylphenye-N,N′-diphenylbenzidine (TPD), 4,4′-cyclohexylidenebis[N,N-bis(4-methylphenyl)benzeneamine] (TACP), a triphenyl tetramer, or the like. The emission layer 110 may be on the hole transport layer 108 and may be formed by doping tris(2-phenylpyridinato)iridium(III) (Ir(ppy)₃) or N,N,N′,N′-tetraphenylbenzidine (TPB) into the indolo[3,2,1-jk] carbazole derivative according to embodiments. The electron transport layer 112 may be on the emission layer 110 and may be formed by using a material including, for example, tris(8-hydroxyquinolinato)aluminum (Alq₃). The electron injection layer 114 may be on the electron transport layer 112 and may be formed by using a material including, for example, lithium fluoride (LiF). The negative electrode 116 may be formed on the electron injection layer 114 and may be formed by using a metal such as Al or a transparent material such as ITO, IZO, or the like.

FIG. 2 is schematic diagram illustrating an organic EL device 200, which is a modification embodiment of the organic EL device 100. The organic EL device 200 is different from the organic EL device 100 in including an intermediate layer 209 between the hole transport layer 108 and the emission layer 110. The intermediate layer 209 may be formed by using the material having the indolo[3,2,1-jk] carbazole skeleton according to embodiments and an electron acceptor. The emission layer 110 may be formed by doping dopants into the indolo[3,2,1-jk] carbazole derivative according to embodiments, as described above.

By using the indolo[3,2,1-jk] carbazole derivative as a host material in the organic EL device according to this embodiment, amorphous properties may be improved, and the dispersibility of the dopants in the host may be increased. In addition, the electron transport properties may be increased, and an emission layer having high efficiency and long life may be formed. In addition, the indolo[3,2,1-jk] carbazole derivative may be applied in an organic EL apparatus of an active matrix using a thin film transistor (TFT).

The following Examples and Comparative Examples are provided in order to highlight characteristics of one or more embodiments, but it is to be understood that the Examples and Comparative Examples are not to be construed as limiting the scope of the embodiments, nor are the Comparative Examples to be construed as being outside the scope of the embodiments. Further, it is to be understood that the embodiments are not limited to the particular details described in the Examples and Comparative Examples.

### Examples

### Synthetic Method

The above-described indolo[3,2,1-jk] carbazole derivative according to embodiments may be synthesized by, for example, the following methods.

### Synthesis of Compound A

Carbazole and 1-fluoro-2-nitrobenzene were heated and refluxed in the presence of potassium carbonate for about 4 hours to produce Compound A with a yield of 82%. Compound A was reduced using a tin powder to be transformed into Compound B with a yield of 89%. Compound B was reacted with sodium nitrite at 0° C. in a solvent mixture of hydrosulfuric acid (concentration 18 vol %) and acetic acid (concentration: 82 vol %), and condensed by a thermal decomposition to produce Compound C with a yield of 62%. Compound C was brominated in chloroform to produce Compound D of a yield of 56%. Compound D was reacted with normal butyl lithium in a tetrahydrofuran (THF) solvent. Triphenylchlorosilane was added and reacted at room temperature for about 1 hour. Then, the reaction mixture was hydrolyzed by using aqueous sodium hydrogen chloride to produce a compound of Example 1 with the yield of 27%.

By conducting the same preparation methods described above, two compounds were prepared as Examples 1 and 2. As comparative examples, three compounds of the Comparative Examples 1, 2, and 3 were prepared.

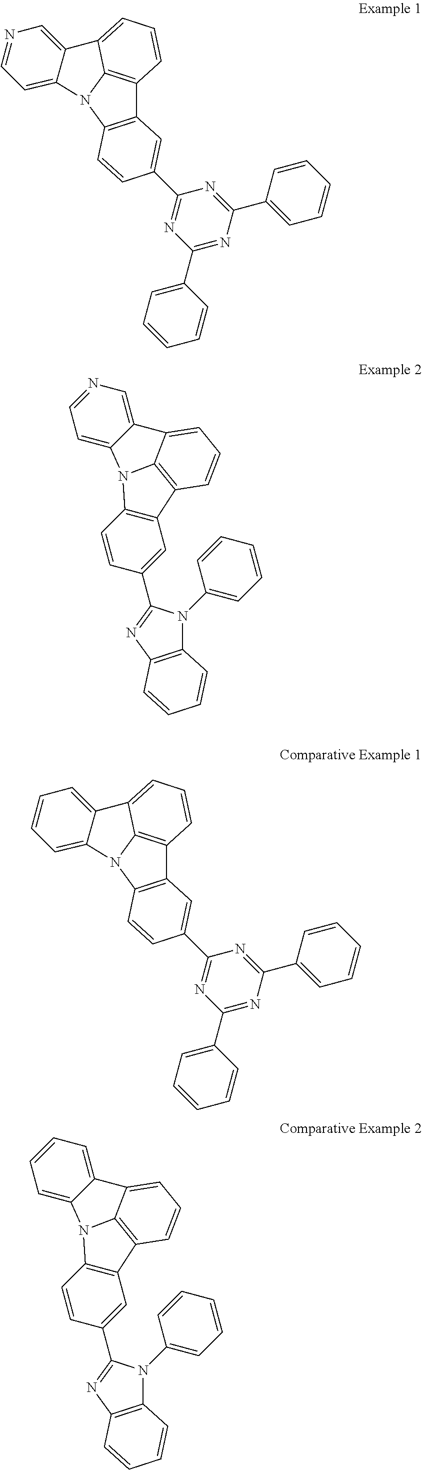 [SMILES: c1ccc(-c2nc(-c3ccccc3)nc(-c3ccc4c(c3)c3cccc5c6cnccc6n4c53)n2)cc1 ; c1ccc(-n2c(-c3ccc4c(c3)c3cccc5c6cnccc6n4c53)nc3ccccc32)cc1 ; c1ccc(-c2nc(-c3ccccc3)nc(-c3ccc4c(c3)c3cccc5c6ccccc6n4c53)n2)cc1 ; c1ccc(-n2c(-c3ccc4c(c3)c3cccc5c6ccccc6n4c53)nc3ccccc32)cc1]

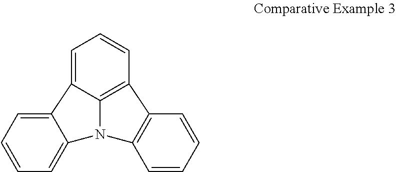 [SMILES: c1ccc2c(c1)c1cccc3c4ccccc4n2c13]

Organic EL devices including emission layers formed by using the host materials of Examples 1 and 2, and Comparative Examples 1 to 3 were manufactured.

### Method of Manufacturing Organic EL Device

By using the compounds of Examples 1 and 2, and Comparative Examples 1 to 3, organic EL devices were manufactured by the following method. On a glass substrate, ITO was formed into a film having a thickness of about 100 nm by a sputtering method and patterned, and ultrasonic wave cleaning was performed in isopropyl alcohol and pure water for 5 minutes, respectively. The substrate was installed in a vacuum deposition apparatus, and a hole injection layer including 1-TNATA and having a thickness of about 60 nm was formed. Then, a hole transport layer including NPD and having a thickness of about 30 nm was formed. An emission layer was obtained by co-depositing Ir(ppy)₃ and the compound of Example 1 at a volume ratio of 10:90 to a thickness of about 40 nm. Then, tris(8-quinolinolato)aluminum was formed to a thickness of about 25 nm (an electron transport layer), lithium fluoride was formed to a thickness of about 1 nm (an electron injection layer), and aluminum was formed to a thickness of about 100 nm (a negative electrode), one by one. The product was taken from the vacuum deposition apparatus and encapsulated using glass to manufacture an organic EL device 101.

The organic EL devices using the compounds according to Example 2 and Comparative Examples 1 to 3 were manufactured by conducting the same procedure except for replacing the compound of Example 1 with the compounds of Example 2 and Comparative Examples 1 to 3, respectively.

With respect to the manufactured organic EL devices, current efficiency (unit: cd/A) at 10,000 nit, a driving voltage, (unit: V), and luminance half-life (unit: hour) were evaluated.

The evaluation results are illustrated in the following Table 1. The values in Table 1 were obtained when the result of Example 1 was 100%.

TABLE 1

| | Current efficiency | Driving voltage | Luminance half-life |
|---|---|---|---|
| Example 1 | 100 | 100 | 100 |
| Example 2 | 100 | 100 | 95 |
| Comparative | 70 | 100 | 60 |
| Example 1 | | | |
| Comparative | 65 | 110 | 50 |
| Example 2 | | | |
| Comparative | 40 | 110 | 20 |
| Example 3 | | | |

As may be seen in Table 1, the organic EL devices including the host materials of Examples 1 and 2 exhibited higher current efficiency than the organic EL devices including the host materials of Comparative Examples 1 to 3. In addition, the host materials of Examples 1 and 2 may be driven by a lower voltage than the host materials of Comparative Examples 1 to 3. With respect to the luminance half-life, the host materials of Examples 1 and 2 exhibited quite a long life when compared to the host materials of Comparative Examples 1 to 3.

By way of summation and review, in the application of an organic EL device to a display apparatus, high efficiency and long life of the organic EL device are desirable. To provide high efficiency and long life, research has been conducted with respect to a host material constituting an emission layer.

As described above, in the indolo[3,2,1-jk] carbazole derivative according to the embodiments, at least one carbon of a benzene ring forming an indolo[3,2,1-jk] carbazole skeleton was replaced with nitrogen. Thus, high amorphous properties may be obtained, and the dispersibility of dopants in a host may be increased. The indolo[3,2,1-jk] carbazole derivative according to embodiments include an electron acceptor. Accordingly, good electron transport properties, high efficiency, and long life may be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. An indolo[3,2,1-jk] carbazole derivative, in which an indolo[3,2,1-jk] carbazole skeleton and an electron acceptor are combined, and at least one carbon atom of a benzene ring forming the indolo[3,2,1-jk] carbazole skeleton is replaced with a nitrogen atom.

2. The indolo[3,2,1-jk] carbazole derivative as claimed in claim 1, wherein the L in Formula 1 is a pyridine derivative, a pyrimidine derivative, a triazine derivative, an imidazole derivative, a dibenzofuran derivative, or a dibenzothiophene derivative.

3. The indolo[3,2,1-jk] carbazole derivative as claimed in claim 1, wherein the indolo[3,2,1-jk] carbazole derivative is represented by following Formula 1: 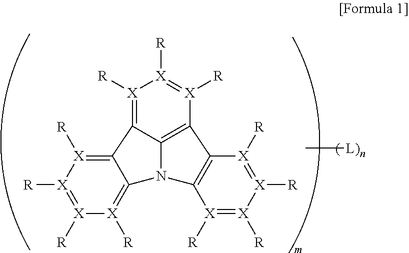
wherein X is a carbon atom or a nitrogen atom,
at least one of X is a nitrogen atom,
when X is a nitrogen atom, R is not present,
when X is a carbon atom, R is hydrogen, an alkyl group, an alkoxy group, an aryl group, or a heteroaryl group,
L is an electron acceptor,
and m and n represent an integer of greater than or equal to 1.

4. The indolo[3,2,1-jk] carbazole derivative as claimed in claim 3, wherein the L in Formula 1 is a pyridine derivative, a pyrimidine derivative, a triazine derivative, an imidazole derivative, a dibenzofuran derivative, or a dibenzothiophene derivative.

5. The indolo[3,2,1-jk] carbazole derivative as claimed in claim 1, being a compound represented by one of the following formulas:

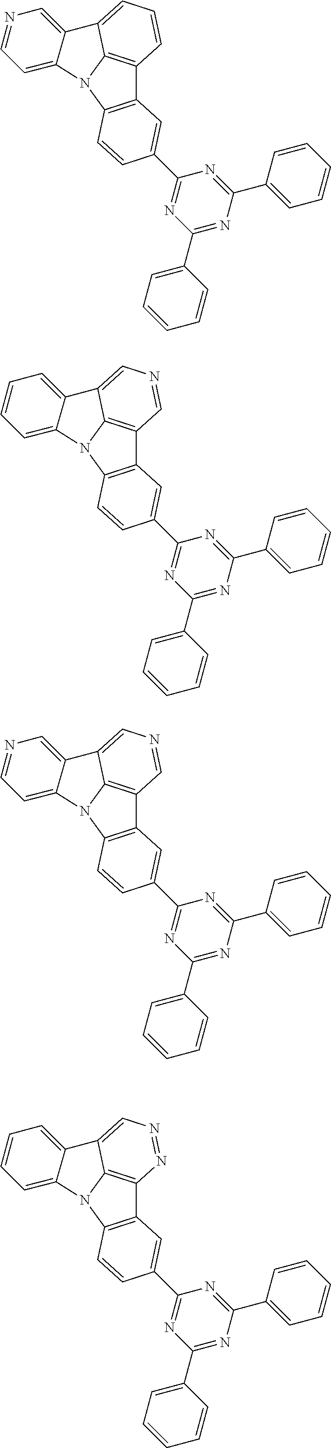

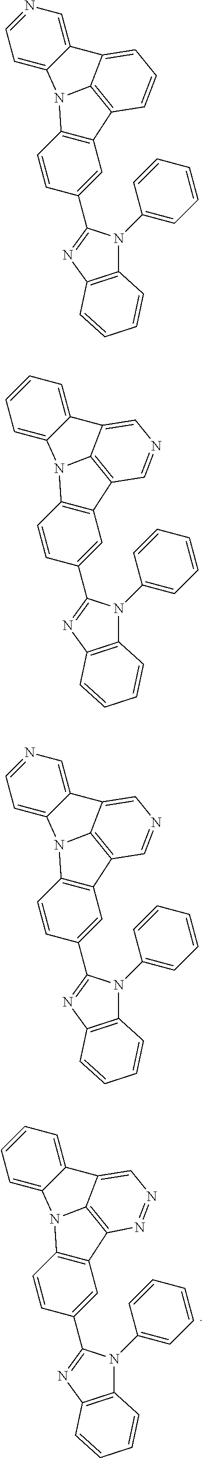 [SMILES: c1ccc(-n2c(-c3ccc4c(c3)c3cccc5c6cnccc6n4c53)nc3ccccc32)cc1 ; c1ccc(-n2c(-c3ccc4c(c3)c3cncc5c6ccccc6n4c53)nc3ccccc32)cc1 ; c1ccc(-n2c(-c3ccc4c(c3)c3cncc5c6cnccc6n4c53)nc3ccccc32)cc1 ; c1ccc(-n2c(-c3ccc4c(c3)c3nncc5c6ccccc6n4c53)nc3ccccc32)cc1]

6. An organic electroluminescence device, comprising an emission layer including an indolo[3,2,1-jk] carbazole derivative, in which an indolo[3,2,1-jk] carbazole skeleton and an electron acceptor are combined, and at least one carbon atom of a benzene ring forming the indolo[3,2,1-jk] carbazole skeleton is replaced with a nitrogen atom.

7. The organic electroluminescence device as claimed in claim 6, wherein the indolo[3,2,1-jk] carbazole derivative is represented by following Formula 1: 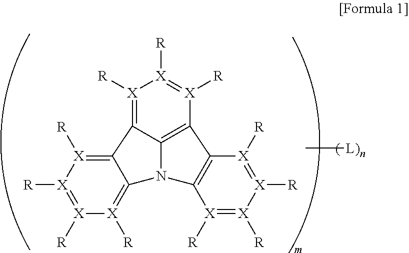
wherein X is a carbon atom or a nitrogen atom,
at least one of X is a nitrogen atom,
when X is a nitrogen atom, R is not present,
when X is a carbon atom, R is hydrogen, an alkyl group, an alkoxy group, an aryl group, or a heteroaryl group,
L is an electron acceptor, and
m and n represent an integer of greater than or equal to 1.

8. The organic electroluminescence device as claimed in claim 7, wherein the L in Formula 1 is a pyridine derivative, a pyrimidine derivative, a triazine derivative, an imidazole derivative, a dibenzofuran derivative, or a dibenzothiophene derivative.

9. The organic electroluminescence device as claimed in claim 6, wherein the indolo[3,2,1-jk] carbazole derivative is a compound represented by one of the following formulas

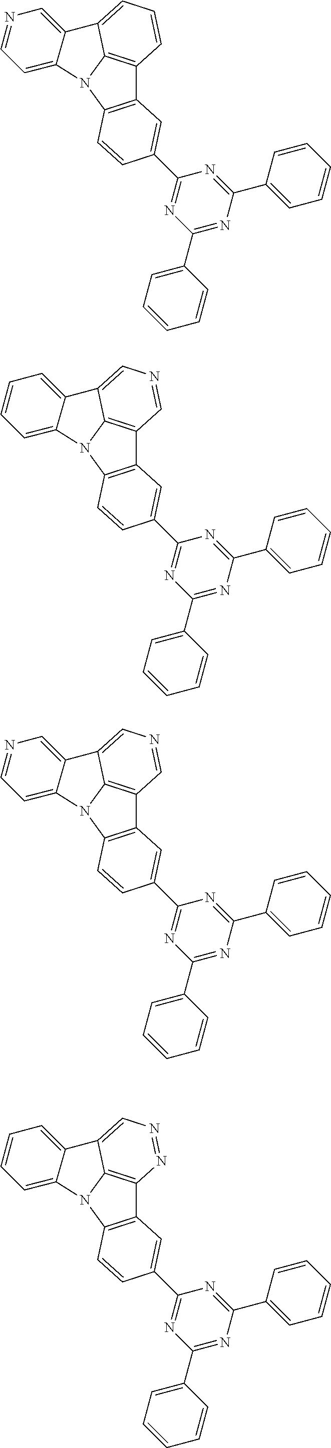

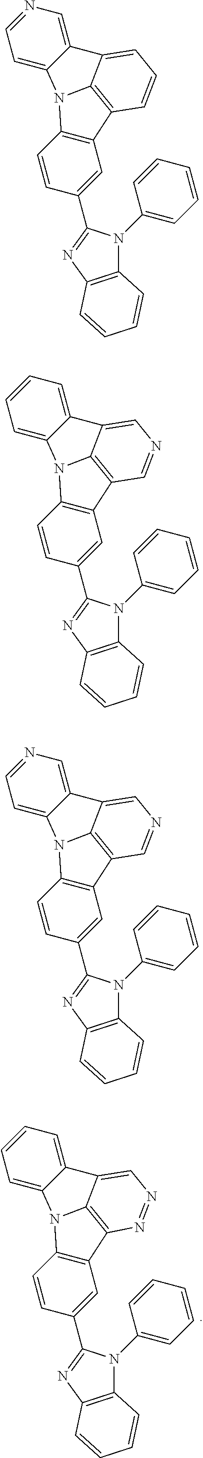 [SMILES: c1ccc(-n2c(-c3ccc4c(c3)c3cccc5c6cnccc6n4c53)nc3ccccc32)cc1 ; c1ccc(-n2c(-c3ccc4c(c3)c3cncc5c6ccccc6n4c53)nc3ccccc32)cc1 ; c1ccc(-n2c(-c3ccc4c(c3)c3cncc5c6cnccc6n4c53)nc3ccccc32)cc1 ; c1ccc(-n2c(-c3ccc4c(c3)c3nncc5c6ccccc6n4c53)nc3ccccc32)cc1]

10. An organic electroluminescence device, comprising an intermediate layer between a hole transport layer and an emission layer,
wherein the intermediate layer includes an indolo[3,2,1-jk] carbazole derivative, in which an indolo[3,2,1-jk] carbazole skeleton and an electron acceptor are combined, and at least one carbon atom of a benzene ring forming the indolo[3,2,1-jk] carbazole skeleton is replaced with a nitrogen atom.

11. The organic electroluminescence device as claimed in claim 10, wherein the indolo[3,2,1-jk] carbazole derivative is represented by following Formula 1: 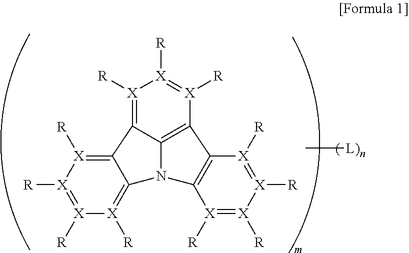
wherein X is a carbon atom or a nitrogen atom,
at least one of X is a nitrogen atom,
when X is a nitrogen atom, R is not present,
when X is a carbon atom, R is hydrogen, an alkyl group, an alkoxy group, an aryl group, or a heteroaryl group,
L is an electron acceptor, and
m and n represent an integer of greater than or equal to 1.

12. The organic electroluminescence device as claimed in claim 10, wherein the L in Formula 2 is a pyridine derivative, a pyrimidine derivative, a triazine derivative, an imidazole derivative, a dibenzofuran derivative, or a dibenzothiophene derivative.

13. The organic electroluminescence device as claimed in claim 10, wherein the indolo[3,2,1-jk] carbazole derivative is a compound represented by one of the following formulas: 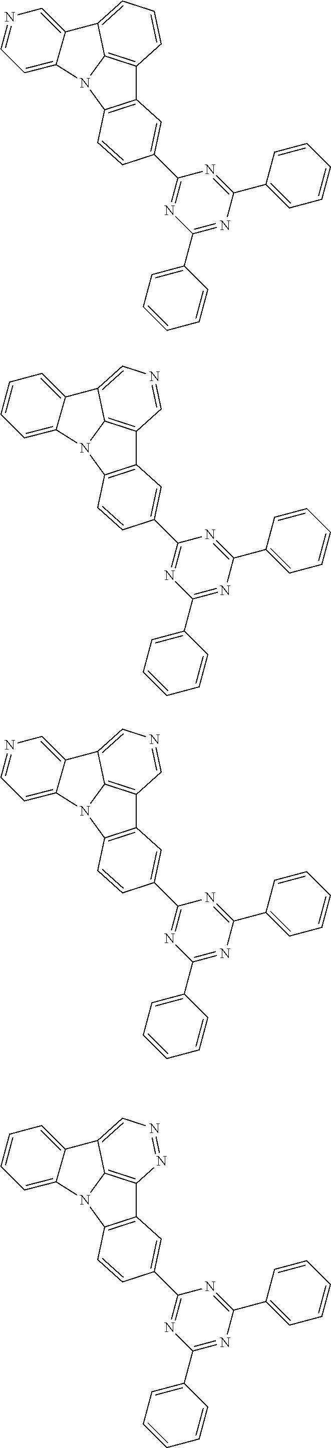 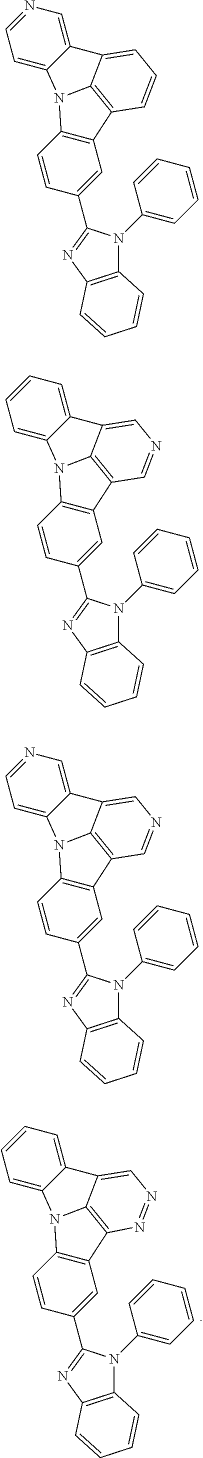 [SMILES: c1ccc(-n2c(-c3ccc4c(c3)c3cccc5c6cnccc6n4c53)nc3ccccc32)cc1 ; c1ccc(-n2c(-c3ccc4c(c3)c3cncc5c6ccccc6n4c53)nc3ccccc32)cc1 ; c1ccc(-n2c(-c3ccc4c(c3)c3cncc5c6cnccc6n4c53)nc3ccccc32)cc1 ; c1ccc(-n2c(-c3ccc4c(c3)c3nncc5c6ccccc6n4c53)nc3ccccc32)cc1]
